(19) United States
(12) Patent Application Publication
(10) Pub. No.: US 2002/0181407 A1
(43) Pub. Date: Dec. 5, 2002

(54) Link quality control by using time dispersion information

(76) Inventors: Anders Khullar, Bjarred (SE); Niklas Stenstrom, Helsingborg (SE); Bengt Lindoff, Bjarred (SE)

Correspondence Address: BURNS DOANE SWECKER & MATHIS L L P, POST OFFICE BOX 1404, ALEXANDRIA, VA, 22313-1404, US

(21) Appl. No.: 09/818,709

(22) Filed: Mar. 28, 2001

(51) Int. Cl. G01R 31/08

(52) U.S. Cl. 370/252; 370/514; 455/69

(57) ABSTRACT

Link quality control information is generated by receiving a received signal from a front end receiver. Time dispersion information is then estimated during a synchronization of the received signal. Then, link quality control information is generated using the time dispersion information. The link quality control information includes information pertaining to an optimal transmission parameter. The link quality control information can be transmitted back to a unit that transmitted the received signal so that the appropriate transmission parameters may be adjusted.

### BACKGROUND

The present invention relates to data communication systems. In particular, the invention relates to methods and apparatuses for controlling link quality in data communication systems.

The cellular telephone industry has made phenomenal strides in commercial operations in the United States as well as the rest of the world. Growth in major metropolitan areas has far exceeded expectations and is rapidly outstripping system capacity. If this trend continues, the effects of this industry's growth will soon reach even the smallest markets. Innovative solutions are required to meet these increasing capacity needs as well as maintain high quality service and avoid raising prices.

In order to increase the capacity in modern Time Division Multiple Access (TDMA) cellular systems, such as Global System for Mobile Communication (GSM) or Enhanced Data rate for GSM Evolutions (EDGE), the receivers have to be quite complex in order to cope with distortion, such as multi-path propagation and the like, and to decode the transmitted data in the receiver. Further, packet data transmission with Link Quality Control (LQC) and Automatic Repeat Request (ARQ) is used in some cellular systems, such as the EDGE system for adapting data rates according to the capacity of the radio link. For instance, if the connection between a mobile terminal and a base station is disturbed by a lot of Inter-Symbol Interference (ISI) due to multi-path propagation, then a lot of redundancy (i.e., coding) is needed to successfully transmit the data. Therefore, the throughput (i.e., the user data rate) will be low. Typically, a highly time dispersive radio channel (i.e., a channel characterized by high levels of ISI) occurs when the mobile terminal is far away from the base station or in hilly terrain. Alternatively, if the mobile terminal is close to the base station, the time dispersion in the radio channel is small. In such cases, it is more likely that the decoder will correctly decode the data (i.e., because of less ISI). Thus, under low ISI conditions, a high throughput can be achieved because little or no coding is required for successful data transmission.

When establishing a connection between a mobile terminal and a base station the time dispersion for the radio channel is unknown. For instance, the mobile terminal may be far away from the base station. In such cases, the time dispersion for the channel will likely be large and will require a large amount of coding. To accommodate this probability, the system may be designed so the initial data transmission between the base station and the mobile terminal starts using the highest coding rate (i.e., the least amount of error correction capability). At the start of transmission many errors can occur, but the base station has to receive a predetermined amount of retransmission requests of erroneous packets according to the ARQ protocol used in the system before the LQC gives the order to change the coding rate. The coding rate then will be reduced gradually until sufficient transmission quality (i.e., an adequate coding rate) is obtained. The time required to stabilize a data connection increases the response time for the user of the mobile terminal and also decreases the capacity of the system.

Alternatively, the system may be designed to initially begin transmitting at a lowest coding rate. However, this too can lead to undesired effects. For example, the radio channel may have a low level of time dispersion at the time of connection establishment, meaning that a very high coding rate may be acceptable. Nonetheless, the system will begin transmitting at the lowest coding rate. The coding rate must then be increased gradually until the LQC determines an unacceptable level of retransmission requests from the mobile terminal, at which point the coding rate is backed off to return to an acceptable level of retransmission requests from the mobile terminal. Again, if the time dispersion were known in advance, the throughput for the user would be greater.

The prior art systems do not provide efficient methods for estimating the time dispersion of the channel and providing the information to the LQC that can speed up the search for optimal transmission parameters, such as coding rates, modulation formats, transmitting unit power output and the like. Therefore, there is a need for efficient methods and systems that estimate the time dispersion of the channel and provide the information to the LQC that facilitates the search for optimal transmission parameters.

### SUMMARY

It should be emphasized that the terms “comprises” and “comprising”, when used in this specification, are taken to specify the presence of stated features, integers, steps or components; but the use of these terms does not preclude the presence or addition of one or more other features, integers, steps, components or groups thereof.

The invention overcomes the prior art limitations by providing improved link quality control methods and apparatuses. The invention includes receiving a received signal from a front end receiver. Time dispersion information is estimated during a synchronization of the received signal. Then, link quality control information is generated using the time dispersion information. The link quality control information includes information pertaining to an optimal transmission parameter. Optionally, the link quality control information is transmitted back to a unit that transmitted the received signal, thereby allowing the transmission parameters, such as coding rate, modulation format, transmitting unit power output and the like, to be rapidly adjusted.

The above features and advantages of the present invention will be more apparent and additional features and advantages of the present invention will be appreciated from the following detailed description of the invention made with reference to the drawings.

### BRIEF DESCRIPTION OF THE DRAWINGS

The objects and advantages of the invention will be understood by reading the following detailed description in conjunction with the drawings in which:

FIG. 1 shows a general radio communication system in which the invention can be implemented;

FIG. 2 shows an exemplary system of the invention; and

FIG. 3 shows a flowchart illustrating a method of the invention that estimates the time dispersion of a channel and provides the information to a LQC.

### DETAILED DESCRIPTION

In the following description, for purposes of explanation and not limitation, specific details are set forth, such as particular circuits, circuit components, techniques, and the like in order to provide a thorough understanding of the present invention. However, it will be apparent to one skilled in the art that the present invention may be practiced in other embodiments that depart from these specific details. In other instances, detailed descriptions of well-known methods, devices, and circuits are omitted so as not to obscure the description of the present invention.

The invention will be described in connection with a number of exemplary embodiments. To facilitate an understanding of the invention, many aspects of the invention are described in terms of sequences of actions to be performed by elements of a computer-based system. It will be recognized that in each of the embodiments, the various actions could be performed by specialized circuits (e.g., discrete logic gates interconnected to perform a specialized function), by program instructions being executed by one or more processors, or by a combination of both. Moreover, the invention can additionally be considered to be embodied entirely within any form of a computer readable storage medium having stored therein an appropriate set of computer instructions that would cause a processor to carry out the techniques described herein. Thus, the various aspects of the invention may be embodied in many different forms, and all such forms are contemplated to be within the scope of the invention. For each of the various aspects of the invention, any such form of an embodiment may be referred to herein as “logic configured to” perform a described action, or alternatively as “logic that” performs a described action.

The exemplary radio communication systems discussed herein are based upon the Time Division Multiple Access (“TDMA”) protocol, in which communication between the base station and the mobile terminals is performed over a number of time slots. However, those skilled in the art will appreciate that the concepts disclosed herein find use in other protocols, including, but not limited to, Frequency Division Multiple Access (“FDMA”), Code Division Multiple Access (“CDMA”), or some hybrid of any of the above protocols. Likewise, some of the exemplary embodiments provide illustrative examples relating to the GSM or EDGE type of systems. However, the techniques described herein are equally applicable to radio communication systems operating in accordance with any specification.

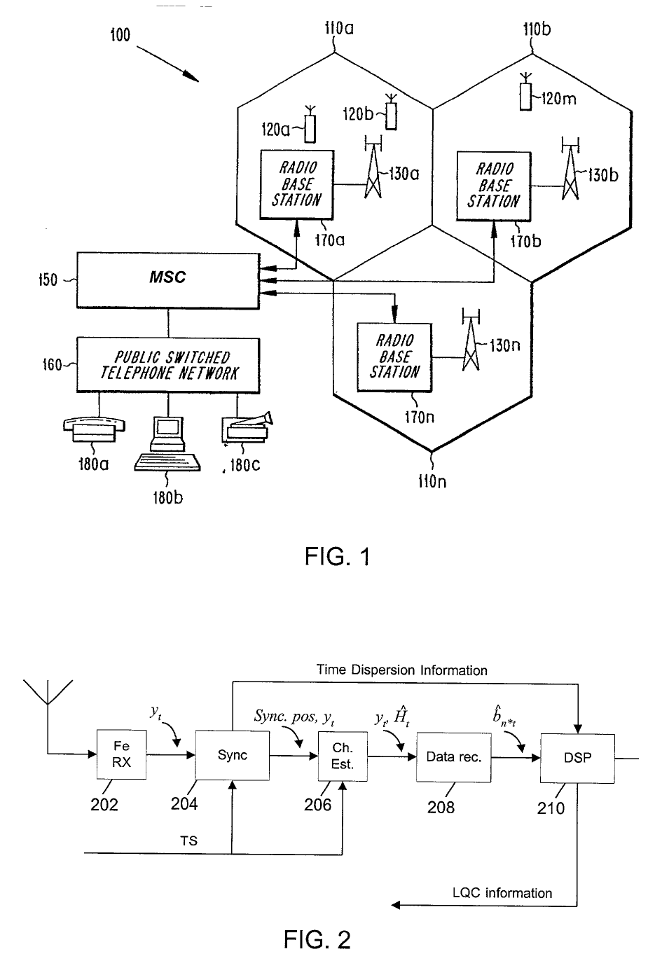

Prior to discussing exemplary embodiments according to the invention, FIG. 1 will now be described which illustrates a general radio communication system 100 in which the invention can be implemented. The radio communication system 100 includes a plurality of radio base stations 170a-n connected to a plurality of corresponding antennae 130a-n. The radio base stations 170a-n in conjunction with the antennae 130a-n communicate with a plurality of mobile terminals (e.g., terminals 120a, 120b, and 120m) within a plurality of cells 110a-n. Communication from a base station to a mobile terminal is referred to as the downlink, whereas communication from a mobile terminal to the base station is referred to as the uplink.

The base stations are connected to a Mobile Switching Center (“MSC”) 150. Among other tasks, the MSC coordinates the activities of the base station, such as during the handoff of a mobile terminal from one cell to another. The MSC 150, in turn, can be connected to a public switched telephone network 160, which services various communication devices 180a, 180b, and 180c. Both the mobile terminals 120a, 120b, and 120m, and the base stations 170a-n can incorporate the system structures and techniques according to the invention.

The invention provides methods and systems for improving the link quality control (LQC), in terms of speed and accuracy, by using information about the time dispersion of the radio channel. The time dispersion is estimated during the synchronization procedure and the information is fed to a control unit that uses this information to propose the LQC and includes information pertaining to an optimal transmission parameter, for example a coding rate proposal. Thus, the coding rate for a particular radio link can be decided faster and more accurately, thereby delivering a higher throughput for the user.

In order to facilitate an understanding of the invention, only a description of the down-link (i.e., from base station to mobile terminal) in a cellular system using LQC is presented below. However, one skilled in the art will appreciate that the invention is equally applicable for the uplink (i.e., from mobile terminal to base station). Additionally, examples involving coding rate proposals as an optimal transmission parameter are described. However, it will be appreciated by those skilled in the art that other parameters, such as modulation, transmitting unit (e.g., base station or mobile terminal) power output, and the like, may be use instead of or in combination with coding rate as the optimal transmission parameter. Finally, although the term proposal is used in connection with the optimal transmission parameter, it will be appreciated that proposal, command, or instruction may be used interchangeably in the context of the invention (e.g., a superior unit may command an inferior unit to change coding rate, whereas an inferior unit may only supply a proposal for a coding rate change to a superior unit).

FIG. 2 shows a block diagram a receiver that uses time dispersion information to enhance the LQC. Assuming a cellular system using burst transmission, a signal (or burst), including data symbols (i.e., information) and known training symbols (i.e., symbols used for synchronization and channel estimation purpose), is received in the antenna. The burst is filtered and down converted to a received signal, yt, in the front end receiver 202 (Fe RX). The received signal is then fed to a synchronization unit 204 (Sync.) that correlates the received signal with a known training sequence (TS) in order to find the synchronization position (i.e., the position within the received signal at which the training sequence starts). Additionally, the time dispersion is estimated in the synchronization unit using techniques described below.

Assume the received signal for a given burst, which has been down converted to a received signal and sampled at symbol rate, is written as:

yₙ=hₒuₙ+ . . . +h_{L}u_{n-L}+eₙ, n=1 . . . ,K

where K is the burst length, H=[hₒ, . . . , h_{L}] is the radio channel, uₖ is the transmitted symbol at time k (i.e., a complex valued number representing n data bits b_{n*t}, b_{n*t+}1 . . . , b_{(n+1)*t-1}), and eₙ is some kind of noise. Further, L is the length or time dispersion of the radio channel and is unknown. However, an upper bound of L, based on worst case scenarios for the present cellular system, is assumed to be known. The correlation in the synchronization unit is well known in the art, (see, J. Proakis, “Digital Communications”, McGraw-Hill Inc., New York, 1995) and is performed by computing the following:

$$c ( k ) = \frac{1}{{n}_{TS}^{i}} {\sum }_{n = 1}^{{n}_{TS}} y ( n + k ) {u}_{TS} ( n ) , k = {n}_{0} , … , {n}_{0} + N , i = 1 , … , M$$

where c(k) is the k-lag cross-correlation between the received signal and the u_{TS}(n), which is the known training sequence. The variable c(k) can also be seen as a coarse estimate of the channel taps hᵢ. Further, N is the synchronization window size and n₀ is the position where the search for the synchronization position starts. Since the time dispersion of the radio channel is unknown, it has to be estimated. This estimation of the time dispersion can be performed in several ways. One way to estimate the time dispersion is to count the number of consecutive c(k) larger than a predetermined value. If c(k) is below that predetermined value it is assumed to be noise and not a channel tap. If the time dispersion is estimated to be Q, then the synchronization position can be computed by maximizing the energy within a window of length Q, such as:

$$Energy ( k ) = {\sum }_{n = k}^{k + Q} {\vert c ( k ) \vert}^{2} , i = 1 , … , M$$

$$Sync . Pos . = {max}_{k ∈ [ 0 , N ]} {\vert Energy ( k ) \vert}^{2}$$

Another way to estimate the time dispersion is to first compute the synchronization position assuming the time dispersion is L (i.e., the maximum allowed time dispersion in the system) and then use more advanced statistical methods (e.g., an Akaike Information Criteria (AIC) test) to estimate the true time dispersion, which may be performed in a channel estimator. The AIC test is described in L. Ljung, System Identification—Theory for the User, Prentice Hall Inc., New Jersey, 1987. Additional descriptions of these techniques can be found in U.S. patent application Ser. No. 09/168,605, filed on Oct. 9, 1998 entitled “Estimated Channel With Variable Number of Taps,” which is hereby incorporated by reference herein in its entirety.

For example, in one embodiment of a receiver that uses the time dispersion information in determining the LQC, the channel filter taps are estimated in a channel estimator using a least squares technique for different model orders (i.e., L=nₘᵢₙ, . . . , nₘₐₓ). The resulting estimates are then Ĥₘᵢₙ, . . . Ĥₘₐₓ. The best model order (Lₒₚₜ), which also gives an estimate of the time dispersion, is chosen according to an AIC model validation test given as:

$${L}_{opt} = arg {min}_{n} log ( {\hat{σ}}_{e}^{2} ( n ) ) + n / N$$

where N is the number of training sequence symbols used in the estimation, n is the model order and \hat{σ}ₑ²(n) is the estimate of the noise power for model order n, given as:

$${\hat{σ}}_{e}^{2} ( n ) = \frac{1}{N} {\sum }_{k = 1}^{N} {\vert {y}_{k} - {\sum }_{i = 0}^{n - 1} {\hat{h}}_{i} {u}_{k - i}^{TS} \vert}^{2} .$$

Therefore, an estimate of the true time dispersion can be advantageously obtained during the channel estimation procedure using the AIC model validation test.

Returning now to the discussion of FIG. 2, the synchronization position together with the received signal are fed to a channel estimation unit (Ch Est) 206 that estimates the channel, Ĥ, for example, using standard Least-Squares techniques or other estimation techniques known in the art. The estimated channel together with the received signal are then fed to the data recovery unit (Data rec) 208 that decodes the data. The data recovery unit 208 includes an equalizer (not shown) that uses the estimated radio channel and the received signal to estimate the received symbols ûₜ, and a channel decoder that, based on a particular coding rate used, estimates the data bits \hat{b}ₜ from the estimated symbols. The estimated data bits are then used in further processing performed by digital signal processor (DSP) 210. DSP 210 also receives time dispersion information obtained in the synchronization unit 204 and includes this time dispersion information in the LQC information. The LQC uses the estimated data bits and time dispersion information to estimate the link quality and propose a coding rate to be used by the base station. The time dispersion information can be mapped to coding rates and then stored in a lookup table, where a priori information about optimal coding rate as a function of the time dispersion is stored. However, one skilled in the art will recognize there are many other methods for mapping the time dispersion information to coding rates. Preferably, the LQC information including the estimated link quality and coding rate proposal are transmitted to the base station. The base station (or MSC) then uses the LQC information to choose the coding rate that is used in the connection between the base station and mobile terminal.

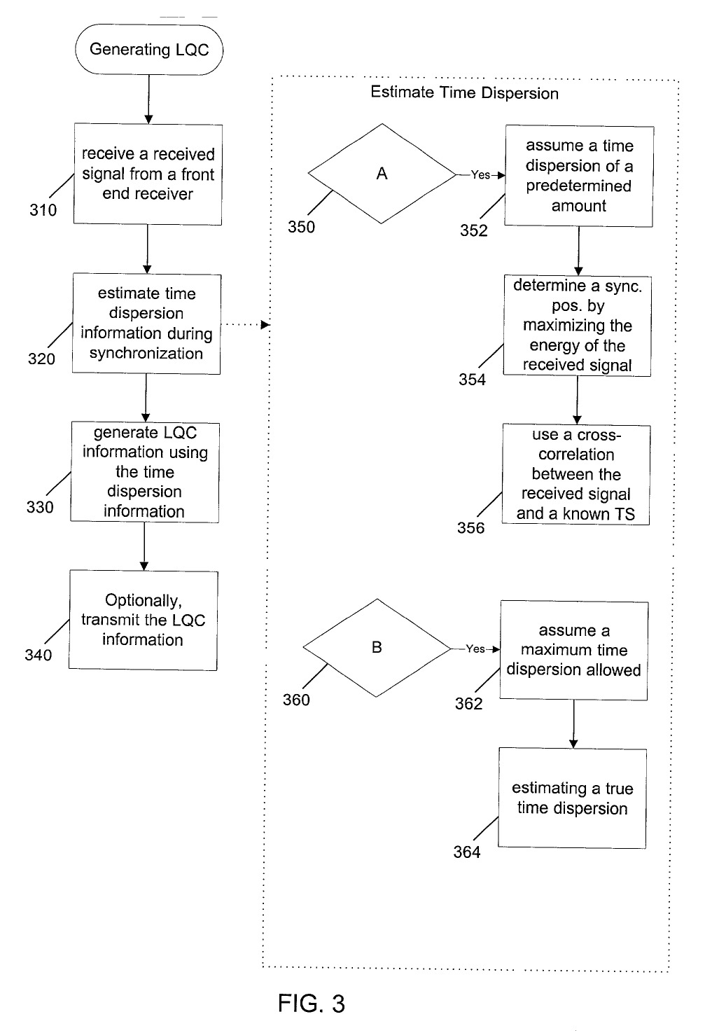

Referring to FIG. 3, a flowchart illustrating an exemplary method of the invention is shown. The method starts by receiving a received signal from a front end receiver, in step 310. The received signal contains a training sequence that is used for synchronization and channel estimation. In step 320, time dispersion information is estimated during a synchronization of the received signal. The link quality control information is generated using the time dispersion information, in step 330. The link quality control information includes an estimated link quality and a coding rate proposal. Optionally, the link quality control information is transmitted to a unit that transmitted the received signal, in step 340. As previously noted, the unit that transmitted the received signal may be a base station or a mobile terminal. In step 350, one method of estimating the time dispersion information is selected. In step 352, a time dispersion of a predetermined amount is assumed, thereby establishing a time dispersion window. A synchronization position is then determined by maximizing the energy of the received signal within the time dispersion window, in step 354. Finally, in step 356, a cross-correlation between the received signal and a known training sequence is used to determine the maximum energy of the received signal within the time dispersion window. Alternatively, in step 360, another method for estimating the time dispersion is selected. A time dispersion is assumed to be equal to a maximum time dispersion allowed for a given system, thereby establishing a time dispersion window, in step 362. Next, in step 364, a true time dispersion is estimated by using an advanced statistical method such as the Akaike Information Criteria test.

The foregoing has described the principles, preferred embodiments and modes of operation of the present invention. However, the invention should not be construed as being limited to the particular embodiments discussed above. For example, the LQC information may be used by other devices instead of the base station/mobile terminal to control the coding rate. For instance, an MSC, such as shown in FIG. 1, may received the LQC information from a variety of mobile terminals and adjust the channel coding for each connection between the mobile terminals and base stations. One skilled in the art will appreciate that there are many variations in system design that may control both the generation of and response to the LQC information in a given system.

Further, the modulation format may be changed in addition to or instead of changing the coding rate based on the LQC information. For example, the modulation format may be changed between Gaussian Minimum Shift Keying (GMSK) and 8-Phase Shift Keying (8-PSK) in response to a change in the LQC. One skilled in the art will appreciate that the modulation formats are not limited to the previously described format change. Instead, it will be appreciated that the invention includes changing from any modulation format to a more advantageous format based on the LQC.

Still further, the output power of the transmitting unit (i.e., base station, mobile terminal, and the like) may be changed to further increase the system throughput based on the LQC. The output power of the transmitting unit may be changed individually or in combination with a coding rate and/or modulation change based on the LQC.

Therefore, the above-described embodiments should be regarded as illustrative rather than restrictive, and it should be appreciated that variations may be made in those embodiments by workers skilled in the art without departing from the scope of the present invention as defined by the following claims.

What is claimed is:

1. A method of generating link quality control information, the method comprising:
receiving a received signal from a front end receiver;
estimating time dispersion information during a synchronization of the received signal; and
generating link quality control information using the time dispersion information, wherein the link quality control information includes information pertaining to an optimal transmission parameter.

2. The method of claim 1 further comprising:
transmitting the link quality control information to a unit that transmitted the received signal.

3. The method of claim 1, wherein estimating time dispersion information comprises:
assuming a time dispersion of a predetermined amount, thereby establishing a time dispersion window; and
determining a synchronization position by maximizing the energy of the received signal within the time dispersion window.

4. The method of claim 3 further comprising:
using a cross-correlation between the received signal and a known training sequence to determine the maximum energy of the received signal within the time dispersion window.

5. The method of claim 1, wherein estimating time dispersion information comprises:
assuming a time dispersion equal to a maximum time dispersion allowed for a given system, thereby establishing a time dispersion window; and
estimating a true time dispersion by a statistical method.

6. The method of claim 5, wherein the statistical method is an Akaike Information Criteria test.

7. The method of claim 1 further comprising:
mapping a coding rate proposal to the time dispersion information using a lookup table containing a priori information about optimal coding rate as a function of the time dispersion, wherein the coding rate proposal is the optimal transmission parameter.

8. The method of claim 1, wherein the optimal transmission parameter is a modulation format proposal.

9. The method of claim 8, wherein the modulation format proposal is a change between Gaussian Minimum Shift Keying and 8-Phase Shift Keying.

10. The method of claim 1, wherein the optimal transmission parameter includes at least one of a coding rate, a modulation format and a transmitting unit power output proposal.

11. A transceiver comprising:
a front end receiver that outputs a received signal;
logic that estimates time dispersion information during a synchronization of the received signal; and
logic that generates link quality control information using the time dispersion information, wherein the link quality control information includes information pertaining to an optimal transmission parameter.

12. The transceiver of claim 11 further comprising:
a transmitter that transmits the link quality control information to a unit that transmitted the received signal.

13. The transceiver of claim 11, wherein the logic that estimates the time dispersion information comprises:
logic that assumes a time dispersion of a predetermined amount, thereby establishing a time dispersion window; and
logic that determines a synchronization position by maximizing the energy of the received signal within the time dispersion window.

14. The transceiver of claim 13 further comprising:
logic that uses a cross-correlation between the received signal and a known training sequence to determine the maximum energy of the received signal within the time dispersion window.

15. The transceiver of claim 11, wherein the logic that estimates the time dispersion information comprises:
logic that assumes a time dispersion equal to a maximum time dispersion allowed for a given system, thereby establishing a time dispersion window; and
logic that estimates a true time dispersion by a statistical method.

16. The transceiver of claim 15, wherein the statistical method is an Akaike Information Criteria test.

17. The transceiver of claim 11 further comprising:
logic that maps a coding rate proposal to the time dispersion information using a lookup table containing a priori information about optimal coding rate as a function of the time dispersion, wherein the coding rate proposal is the optimal transmission parameter.

18. The transceiver of claim 11, wherein the transceiver is a base station.

19. The transceiver of claim 11, wherein the transceiver is a mobile terminal.

20. The transceiver of claim 11, wherein the optimal transmission parameter is a modulation format proposal.

21. The transceiver of claim 20, wherein the modulation format proposal is a change between Gaussian Minimum Shift Keying and 8-Phase Shift Keying.

22. The transceiver of claim 11, wherein the optimal transmission parameter includes at least one of a coding rate, a modulation format and a transmitting unit power output proposal.
